(19) United States
(12) Patent Application Publication
(10) Pub. No.: US 2018/0331694 A1
(43) Pub. Date: Nov. 15, 2018

(54) TRANSMISSION APPARATUS, RECEPTION APPARATUS, AND RECEPTION METHOD

(71) Applicant: FUJITSU LIMITED, Kawasaki-shi (JP)

(72) Inventors: Kouichi YATSU, Kawasaki (JP); TORU INABA, Yokohama (JP); DANASIRI WIJEDASA DEWAGAMAGE, Yokohama (JP)

(73) Assignee: FUJITSU LIMITED, Kawasaki-shi (JP)

(21) Appl. No.: 15/970,975

(22) Filed: May 4, 2018

(30) Foreign Application Priority Data
May 9, 2017 (JP) 2017-092953

(51) Int. Cl. H03M 13/11; G06F 11/30; H04J 14/02; H04J 3/16

(52) U.S. Cl. CPC H03M 13/1105; G06F 11/3062; H04J 2203/0085; H04J 3/1664; H04J 14/0221

(57) ABSTRACT

A transmission apparatus includes: a memory; a processor coupled to the memory, wherein the processor: generates a frame including an input packet; performs, on the frame, a coding process regarding an error correction and depending on whether the packet includes significant data; and transmits the frame subjected to the coding process.

### CROSS-REFERENCE TO RELATED APPLICATION

This application is based upon and claims the benefit of priority of the prior Japanese Patent Application No. 2017-092953, filed on May 9, 2017, the entire contents of which are incorporated herein by reference.

### FIELD

Embodiments relate to a transmission apparatus, a reception apparatus, and a reception method.

### BACKGROUND

An optical communication system includes, for example, an Optical Transport Network (OTN). An error in data transmission is detected and corrected. Examples of techniques of error correction in data transmission includes Forward Error Correction (FEC).

Related techniques are disclosed in Japanese Laid-open Patent Publication No. 2006-332920 and Japanese National Publication of International Patent Application No. 2008-527948.

### SUMMARY

According to an aspect of the embodiments, a transmission apparatus includes: a memory; a processor coupled to the memory, wherein the processor: generates a frame including an input packet; performs, on the frame, a coding process regarding an error correction and depending on whether the packet includes significant data; and transmits the frame subjected to the coding process.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a communication system;

FIG. 2 illustrates an example of a network to which a communication system is applied;

FIG. 3 illustrates an example of a node apparatus;

FIG. 4 illustrates an example of a communication apparatus;

FIG. 5 illustrates an example of a configuration of a transmission part of a communication apparatus;

FIG. 6 illustrates an example of a configuration of a reception part of a communication apparatus;

FIG. 7 illustrates an example of an OTN frame;

FIG. 8 illustrates an example of setting in terms of FEC operation circuit selection information;

FIGS. 9A and 9B illustrate an example of a process performed in a communication apparatus at a transmission side when an Ethernet packet (significant packet) is received;

FIGS. 10A and 10B illustrate an example of a process performed in a communication apparatus at a transmission side when an Ethernet packet (idle packet) is received;

FIG. 11 illustrates an example of a process performed in a communication apparatus at a transmission side when no Ethernet packet is received;

FIG. 12 illustrates an example of a process performed in a communication apparatus at a reception side when a valid OTN frame (significant packet) is received;

FIG. 13 illustrates an example of a process performed in a communication apparatus at a reception side when an invalid OTN frame (significant packet) is received;

FIG. 14 illustrates an example of a process performed in a communication apparatus at a transmission side when an Ethernet packet is received;

FIG. 15 illustrates an example of a process performed in a communication apparatus at a transmission side when no Ethernet packet is received; and

FIG. 16 illustrates an example of a process performed in a communication apparatus at a reception side when an OTN frame is received.

### DESCRIPTION OF EMBODIMENTS

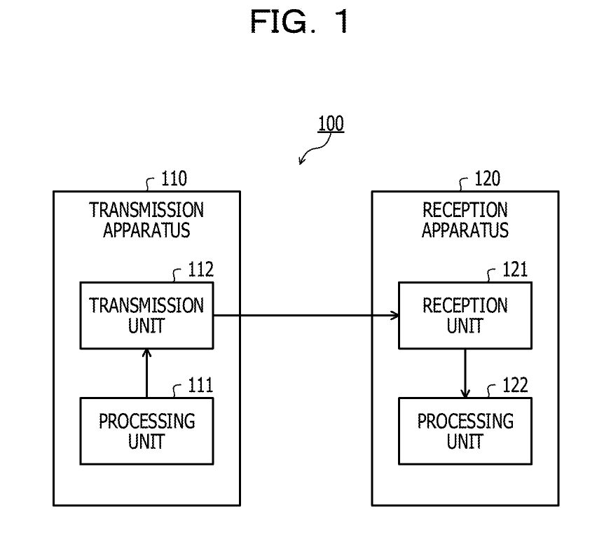

FIG. 1 illustrates an example of a communication system. As illustrated in FIG. 1, the communication system 100 includes a transmission apparatus 110 and a reception apparatus 120. The transmission apparatus 110 is an apparatus that transmits optical signal to the reception apparatus 120 via, for example, an optical transmission channel.

The transmission apparatus 110 includes, for example, a processing unit 111 and a transmission unit 112. The processing unit 111 is input with a packet to be transmitted to the reception apparatus 120. This packet is applied, for example, irregularly, to the processing unit 111. This packet may be an Ethernet packet according to the Ethernet protocol. However, the packet is not limited to the Ethernet packet, but the packet may be one of various other kinds of packets.

The processing unit 111 generates a frame including the input packet. This frame is, for example, a frame to be transmitted periodically by the transmission unit 112. This frame may be an OTN frame according to the OTN (Optical Transport Network) protocol. However, the frame is not limited to the OTN frame, but the frame may be one of various other kinds of frames.

The processing unit 111 performs, on the generated frame, an error correction coding process depending on whether the packet stored in the generated frame includes significant data. An example of significant data is user data. An example of a packet including no significant data is an idle packet.

For example, in a case where a packet in the generated frame includes significant data, the processing unit 111 performs a first coding process on this frame to add a redundant bit calculated in the error correction operation to the frame. For example, the error correction operation is an operation based on the generated frame.

In a case where the packet in the generated frame includes no significant data, the processing unit 111 performs a second coding process, which consumes less power than poser consumed by the first coding process, on this frame. The second coding process is, for example, a process of adding predetermined redundant bits to a frame without performing an error correction operation. However, the second coding process is not limited to this example, but the second coding process may be one of various processes that is lower in consumption power than the first coding process. For example, the second coding process may be a process of performing an error correction operation with lower power consumption than the power consumption of the error correction operation in the first coding process and adding the calculated redundant bit.

When no packet is input, the processing unit 111 may generate, for example, a predetermined idle packet and may generate a frame including the generated idle packet. In this case, the processing unit 111 performs the second coding process on the generated frame.

The processing unit 111 outputs the frame subjected to coding process to the transmission unit 112. The transmission unit 112 transmits the frame output from the processing unit 111 to the reception apparatus 120, for example, via an optical transmission channel.

The reception apparatus 120 includes, for example, a reception unit 121 and a processing unit 122. The reception unit 121 receives the frame transmitted by the transmission apparatus 110. The reception unit 121 outputs the received frame to the processing unit 122. The processing unit 122 performs a decoding process on the frame received by the reception unit 121. The processing unit 122 acquires a packet from the frame subjected to decoding process, and outputs the acquired packet.

As described above, the transmission apparatus 110 is capable of performing an error correction coding process on a frame in a different manner depending on whether a packed stored in the frame includes a significant data, and transmitting the frame subjected to the coding process to the reception apparatus 120. This makes it possible to perform an error correction coding process, for example, such that when a frame does not include a significant data, an error correction coding process with low power consumption is performed thereby achieving a reduction in consumption power.

The processing unit 111 of the transmission apparatus 110 may describe information, in a header of the generated frame, as to a coding process performed on this frame. The reception apparatus 120 performs a decoding process corresponding to the coding process performed by the transmission apparatus 110 based on the information included in the header of the frame received from the transmission apparatus 110.

In this process, the processing unit 111 may store information indicating the coding process in a plurality of area of the header of the frame. This makes it possible to transmit the information indicating the coding process, in a redundant manner, to the reception apparatus 120. For example, the reception apparatus 120 is capable of determining whether the information indicating the coding process has been correctly received from the transmission apparatus 110 by checking whether there is no difference among information stored in the respective areas of the header of the frame received from the transmission apparatus 110.

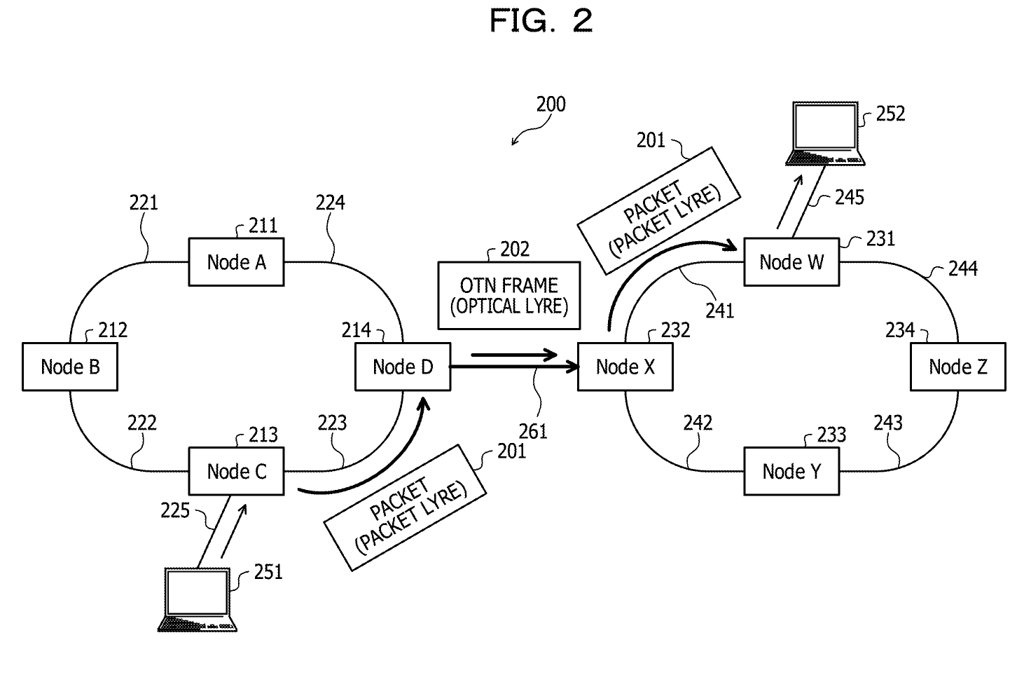

FIG. 2 illustrates an example of a network to which a communication system is applied. The communication system 100 illustrated in FIG. 1 may be applied, for example, to a network 200 illustrated in FIG. 2. The network 200 includes nodes 211 to 214 and 231 to 234, Ethernet transmission channels 221 to 224 and 241 to 244, and an OTN transmission channel 261.

The nodes 211 to 214 (Nodes A to D) are connected to each other in the form of a ring via the Ethernet transmission channels 221 to 224. The nodes 231 to 234 (Nodes W to Z) are connected to each other in the form of a ring via the Ethernet transmission channels 241 to 244. The nodes 214 and 232 are connected to each other via the OTN transmission channel 261. The node 213 is connected to a user terminal 251 via the Ethernet transmission channel 225. The node 231 is connected to a user terminal 252 via the Ethernet transmission channel 245.

The Ethernet transmission channels 221 to 224 and 241 to 244 are transmission channels that support Ethernet communication. Ethernet is a registered trademark. The OTN transmission channel 261 is a transmission channel that supports OTN communication. The Ethernet transmission channel 221 is a transmission channel between the nodes 211 and 212. The Ethernet transmission channel 222 is a transmission channel between the nodes 212 and 213. The Ethernet transmission channel 223 is a transmission channel between the nodes 213 and 214. The Ethernet transmission channel 224 is a transmission channel between the nodes 214 and 211. The Ethernet transmission channel 241 is a transmission channel between the nodes 231 and 232. The Ethernet transmission channel 242 is a transmission channel between the nodes 232 and 233. The Ethernet transmission channel 243 is a transmission channel between the nodes 233 and 234. The Ethernet transmission channel 244 is a transmission channel between the nodes 234 and 231

In FIG. 2, the user terminal 251 transmits a packet 201 (packet layer) addressed to the user terminal 252. The packet 201 is transmitted to the node 214 via the Ethernet transmission channel 225, the node 213, and the Ethernet transmission channel 223, and is converted by the node 214 to an OTN frame 202 (optical layer). The converted OTN frame 202 is transmitted to the node 232 via the OTN transmission channel 261. At the node 232, the OTN frame 202 is converted into the original packet 201 by the node 232 and is transmitted to the user terminal 252 via the Ethernet transmission channel 241, the node 231, and the Ethernet transmission channel 245.

The transmission apparatus 110 illustrated in FIG. 1 is, for example, a transmission unit in the node 214, and is applicable to a transmission unit that transmits the OTN frame 202 to the node 232 via the OTN transmission channel 261. The reception apparatus 120 illustrated in FIG. 1 is, for example, a reception unit in the node 232, and is applicable to a reception unit that receives the OTN frame 202 from the node 214 via the OTN transmission channel 261.

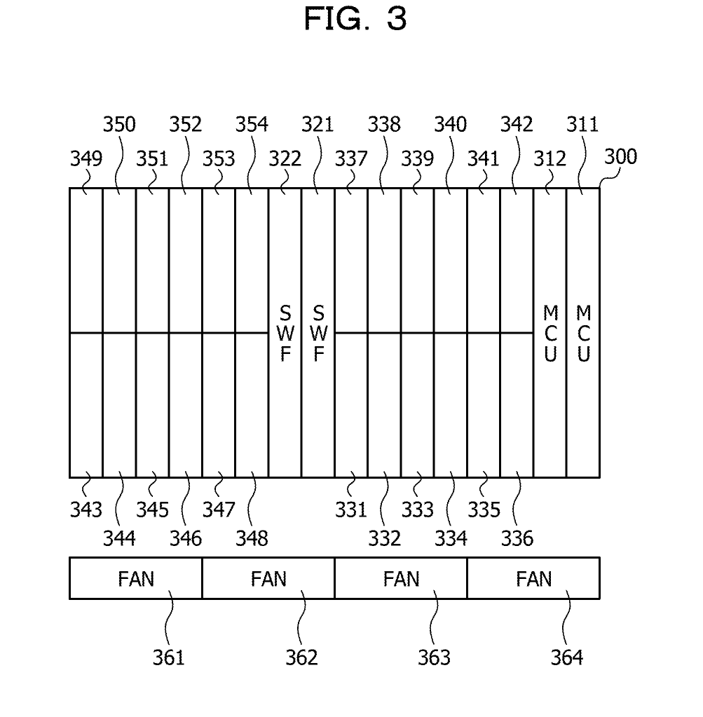

FIG. 3 illustrates an example of a node apparatus. The nodes 211 to 214 and 231 to 234 illustrated in FIG. 2 each may be realized, for example, by the node apparatus 300 illustrated in FIG. 3. The node apparatus 300 includes MCUs 311 and 312, SWF units 321 and 322, an LIUs 331 to 354, and fan units (FAN) 361 to 364. MCU stands for Monitoring and Control Unit. SWF stands for SWitch Fabric. LIU stand for Line Interface Unit.

The MCUs 311 and 312 are each a unit that monitors and controls the whole node apparatus 300. The SWF units 321 and 322 are each a unit having a cross-connect capability for connecting elements of the node apparatus 300 to each other. The LIUs 331 to 354 are each a communication unit that transmits and receives a main signal. The fan units 361 to 364 are each a unit that cools the node apparatus 300.

The node 214 illustrated in FIG. 2 is further described below for a case where the node 214 is applied to the node apparatus 300. In this case, the LIUs 331 to 354 includes an LIU that receives a packet 201 from the node 213, converts the received packet 201 into an OTN frame 202, and transmits the OTN frame 202 to the node 232 via the OTN transmission channel 261.

For example, the node 232 illustrated in FIG. 2 may be applied to the node apparatus 300. In this case, the LIUs 331 to 354 includes an LIU that receives the OTN frame 202 from the node 214 via the OTN transmission channel 261, converts the received OTN frame 202 into a packet 201, and transmits the converted packet 201 to the node 231.

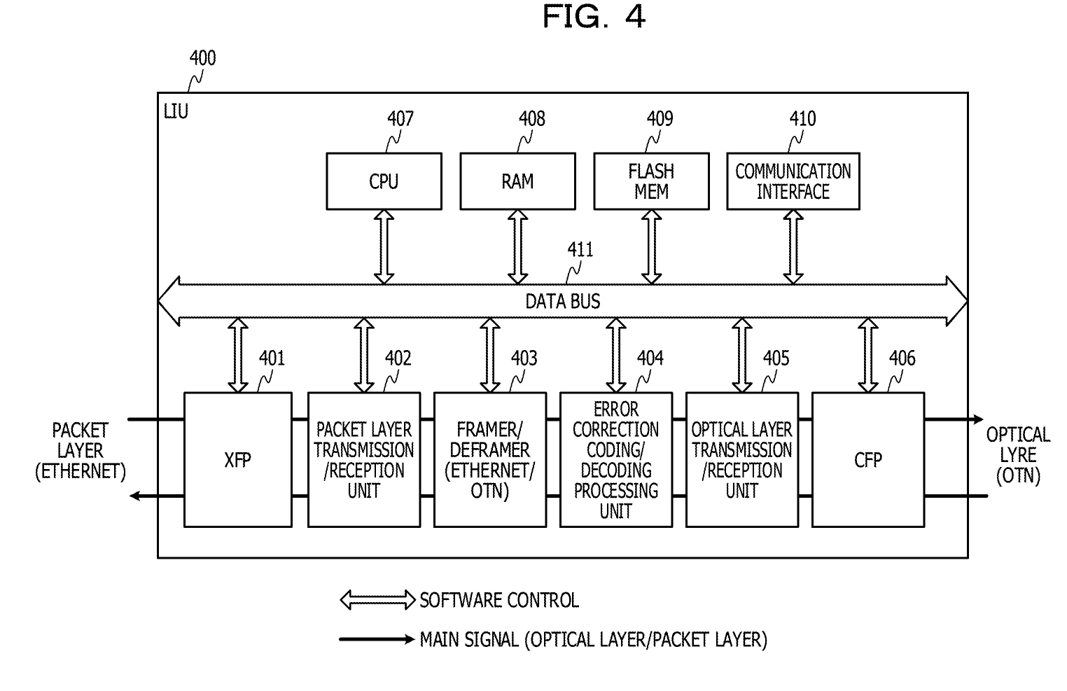

FIG. 4 illustrates an example of a communication apparatus. In FIG. 4, double-headed arrows each indicate software control, while single-headed arrows each indicate a flow of a main signal in an optical layer or a packet layer. Among the LIUs 331 to 354 illustrated in FIG. 3, an LIU that supports the packet layer (Ethernet) and the optical layer (OTN) may be realized, for example, by the communication apparatus 400 illustrated in FIG. 4. The communication apparatus 400 includes an XFP 401, a packet layer transmission/reception unit 402, a framer/deframer 403, an error correction coding/decoding processing unit 404, an optical layer transmission/reception unit 405, and a CFP 406. The communication apparatus 400 also includes a CPU 407, a RAM 408, a flash memory (FLASH MEM) 409, and a communication interface 410. These elements of the communication apparatus 400 are connected to each other via a data bus 411.

XFP stands for 10 Gigabit Small Form-Factor Pluggable. CFP stands for Centum gigabit Form-Factor Pluggable. CPU stands for Central Processing Unit. RAM stands for Random Access Memory.

The packet layer transmission/reception unit 402, the framer/deframer 403, the error correction coding/decoding processing unit 404, and the optical layer transmission/reception unit 405 each may be realized, for example, by a digital circuit such as an FPGA, an LSI, or the like. FPGA stands for Field Programmable Gate Array. LSI stands for Large Scale Integration.

The XFP 401 is a communication interface that supports the packet layer. For example, the XFP 401 receives an Ethernet packet (main signal) from a transmission channel in the packet layer and outputs the received Ethernet packet to the packet layer transmission/reception unit 402. When the XFP 401 receives an Ethernet packet output from the packet layer transmission/reception unit 402, the XFP 401 transmits the received Ethernet packet to the packet layer. However, the communication interface that supports the packet layer is not limited to the XFP, but the communication interface may be another type of communication interface that supports, for example, QSFP, SFP+, or the like. QSFP stand for Quad Small Form-Factor Pluggable. SFP+ stands for Small Form-Factor Pluggable Plus.

The packet layer transmission/reception unit 402 performs a packet layer reception process on an Ethernet packet output from the XFP 401 and outputs the resultant Ethernet packet subjected to the reception process to the framer/deframer 403. The packet layer transmission/reception unit 402 also performs a packet layer transmission process on an Ethernet packet output from the framer/deframer 403 and outputs the resultant Ethernet packet subjected to the transmission process to the XFP 401.

The framer/deframer 403 converts (frames) the Ethernet packet output from the packet layer transmission/reception unit 402 into an OTN frame, and outputs the resultant converted OTN frame to the error correction coding/decoding processing unit 404. The framer/deframer 403 also converts (deframes) an OTN frame output from the error correction coding/decoding processing unit 404 into an Ethernet packet and outputs the resultant converted Ethernet packet to the packet layer transmission/reception unit 402.

The error correction coding/decoding processing unit 404 performs an error-correction coding on the OTN frame output from the framer/deframer 403 and outputs the resultant OTN frame subjected to the error-correction coding to the optical layer transmission/reception unit 405. The error correction coding/decoding processing unit 404 also performs an error correction by error-correction decoding on an OTN frame output from the optical layer transmission/reception unit 405 and outputs the resultant error-corrected OTN frame to the framer/deframer 403.

The optical layer transmission/reception unit 405 performs a transmission process on the OTN frame output from the error correction coding/decoding processing unit 404 and outputs the resultant OTN frame subjected to the transmission process to the CFP 406. The optical layer transmission/reception unit 405 also performs an optical layer reception process on an OTN frame output from the CFP 406 and outputs the resultant OTN frame subjected to the reception process to the error correction coding/decoding processing unit 404.

The CFP 406 is a communication interface that supports the optical layer. For example, the CFP 406 transmits the OTN frame output from the optical layer transmission/reception unit 405 to a transmission channel of the optical layer (OTN). The CFP 406 also receives an OTN frame (main signal) from the optical layer transmission channel and outputs the received OTN frame to the optical layer transmission/reception unit 405. However, the communication interface that supports the optical layer is not limited to the CFP but another communication interface that supports, for example, CFP2 or the like may be employed.

The CPU 407 is, for example, a processor responsible for controlling the whole communication apparatus 400. The RAM 408 is used as a work area by the CPU 407. The flash memory 409 is a non-volatile memory used as an auxiliary memory. In the flash memory 409, various kinds of programs for operating the communication apparatus 400 are stored. The programs stored in the flash memory 409 are loaded into the RAM 408 and executed by the CPU 407.

The communication interface 410 is a communication interface for allowing the communication apparatus 400 to communicate with an external apparatus (for example, MCUs 311 and 312) to transmit and receive a signal other than the main signal. The communication by the communication interface 410 is controlled, for example, by the CPU 407.

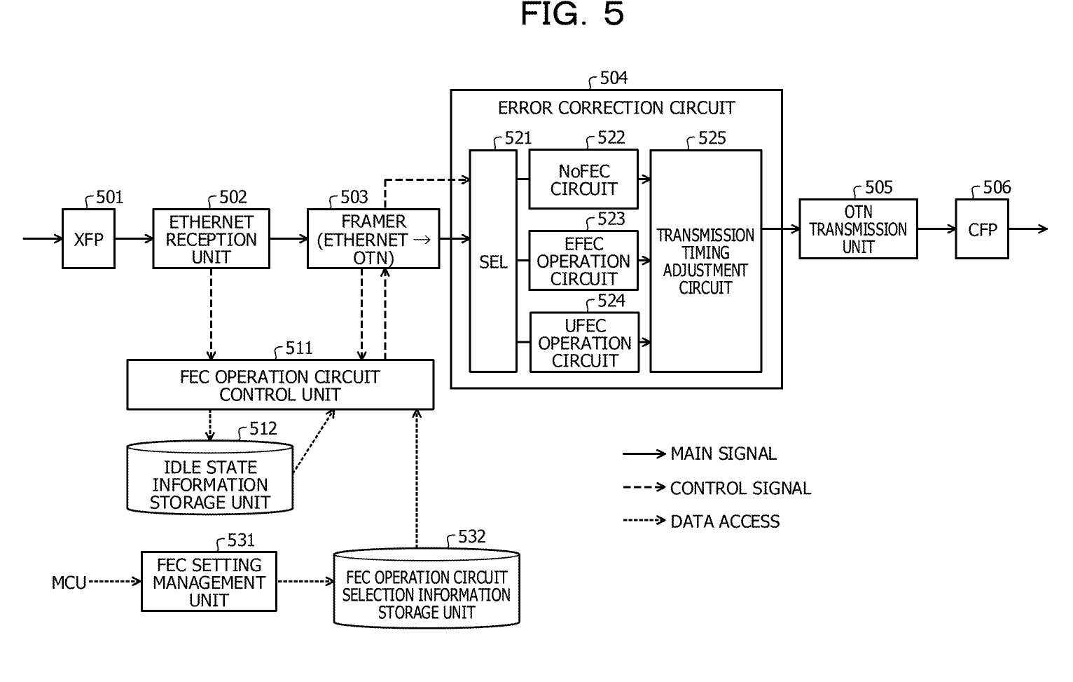

FIG. 5 illustrates an example of a configuration of a transmission part of a communication apparatus. In FIG. 5, solid arrows indicate a main signal flow, broken line arrows indicate a control signal flow, and dotted line arrows indicate data access. The communication apparatus 400 illustrated in FIG. 4 includes, for example, as illustrated in FIG. 5, an XFP 501, an Ethernet reception unit 502, a framer 503, an error correction circuit 504, an OTN transmission unit 505, and a CFP 506. The communication apparatus 400 also includes an FEC operation circuit control unit 511, an idle state information storage unit 512, an FEC setting management unit 531, and an FEC operation circuit selection information storage unit 532.

The FEC operation circuit control unit 511 may be realized, for example, by the CPU 407 illustrated in FIG. 4. The idle state information storage unit 512 and the FEC operation circuit selection information storage unit 532 may be realized, for example, by the RAM 408 or the flash memory 409 illustrated in FIG. 4. The FEC setting management unit 531 may be realized, for example, by the CPU 407 and the communication interface 410 illustrated in FIG. 4.

The XFP 501 is included, for example, in the XFP 401 illustrated in FIG. 4. For example, the XFP 501 converts an Ethernet packet (main signal) received from a packet layer transmission channel from an optical signal to an electric signal and outputs the resultant Ethernet packet converted into the electric signal to the Ethernet reception unit 502.

The Ethernet reception unit 502 is included, for example, in the packet layer transmission/reception unit 402 illustrated in FIG. 4. For example, the Ethernet reception unit 502 performs a packet layer reception process on the Ethernet packet output from the XFP 501 and outputs the resultant Ethernet packet subjected to the reception process to the framer 503. The Ethernet reception unit 502 determines whether the Ethernet packet subjected to the reception process is a significant packet or an idle packet. In a case where it is determined that the Ethernet packet subjected to the reception process is a significant packet, the Ethernet reception unit 502 outputs an Ethernet packet reception notification to the FEC operation circuit control unit 511 to notify that a significant Ethernet packet has been received.

The framer 503 is included, for example, in the framer/deframer 403 illustrated in FIG. 4. For example, the framer 503 converts an Ethernet packet output from the Ethernet reception unit 502 into an OTN frame and outputs the resultant converted OTN frame to the error correction circuit 504.

At each scheduled periodic timing of generating an OTN frame, the framer 503 outputs a frame generation confirmation to the FEC operation circuit control unit 511. The OTN frame generating timing is periodical timing of starting generating an OTN frame, for example, in response to a periodic OTN frame transmission timing. When the error correction circuit switching notification is output from the FEC operation circuit control unit 511 in response to the frame generation confirmation output from the framer 503, the framer 503 outputs an error correction circuit selection notification to the error correction circuit 504 to notify of the error correction circuit specified by the error correction circuit switching notification.

The error correction circuit 504 is included, for example, in the error correction coding/decoding processing unit 404 illustrated in FIG. 4. The error correction circuit 504 includes, for example, selector 521 (SEL), a NoFEC circuit 522, an EFEC operation circuit 523, a UFEC operation circuit 524, and a transmission timing adjustment circuit 525. EFEC stands for Enhanced Forward Error Correction. UFEC stands for Ultra Forward Error Correction.

The selector 521 switches the error correction circuit 504 that processes the OTN frame output from the framer 503. For example, the selector 521 outputs the OTN frame supplied from the framer 503 to an error correction circuit which is one of the NoFEC circuit 522, the EFEC operation circuit 523, and the UFEC operation circuit 524 and which is specified by the error correction circuit selection notification output from the framer 503.

The NoFEC circuit 522 adds predetermined redundant bits to the OTN frame output from the selector 521 where the predetermined redundant bits are bits that are employed in a case where the FEC operation and the error correction operation are not performed. The NoFEC circuit 522 outputs the OTN frame with the added redundant bits to the transmission timing adjustment circuit 525.

The EFEC operation circuit 523 performs the EFEC operation on the OTN frame output from the selector 521 and adds redundant bits obtained as a result of the EFEC operation thereto. The EFEC operation circuit 523 outputs the resultant OTN frame added with the redundant bits to the transmission timing adjustment circuit 525.

The UFEC operation circuit 524 perform a UFEC operation on the OTN frame output from the selector 521 and adds redundant bits obtained as a result of the UFEC operation to the OTN frame. The UFEC operation circuit 524 outputs the resultant OTN frame added with the redundant bits to the transmission timing adjustment circuit 525.

The transmission timing adjustment circuit 525 outputs, to the OTN transmission unit 505, the OTN frame output from one of the NoFEC circuit 522, the EFEC operation circuit 523 and the UFEC operation circuit 524. The transmission timing adjustment circuit 525 adjusts the timing of outputting the OTN frame to the OTN transmission unit 505 thereby adjusting the timing of transmitting the OTN frame from the communication apparatus 400. For example, the transmission timing adjustment circuit 525 adjusts the transmission timing by adjusting a delay time that occurs in the NoFEC circuit 522, the EFEC operation circuit 523 or the UFEC operation circuit 524. This may reduce a loss of data or the like that might occur when the error correction circuit is switched.

The OTN transmission unit 505 is included, for example, in the optical layer transmission/reception unit 405 illustrated in FIG. 4. For example, the OTN transmission unit 505 performs an optical layer transmission process on the OTN frame output from the error correction circuit 504 and outputs the resultant OTN frame subjected to the transmission process to the CFP 506.

The CFP 506 is included, for example, in the CFP 406 illustrated in FIG. 4. For example, the CFP 506 converts the OTN frame output from the OTN transmission unit 505 from an electric signal to an optical signal, and transmits the resultant OTN frame converted to the optical signal to the optical layer (OTN) transmission channel.

When the Ethernet packet reception notification is output from the Ethernet reception unit 502, the FEC operation circuit control unit 511 sets “1” in idle state information stored in the idle state information storage unit 512 to indicate that there is received data.

When the frame generation confirmation is output from the framer 503, the FEC operation circuit control unit 511 reads out the idle state information stored in the idle state information storage unit 512. In a case where the read idle state information is “1”, the FEC operation circuit control unit 511 reads out the FEC operation circuit selection information stored in the FEC operation circuit selection information storage unit 532. The FEC operation circuit control unit 511 outputs an error correction circuit switching notification to the framer 503 to notify of the error correction circuit specified by the read FEC operation circuit selection information.

In a case where the read idle state information is “0”, the FEC operation circuit control unit 511 outputs an error correction circuit switching notification to the framer 503 to notify of the NoFEC. After the FEC operation circuit control unit 511 reads out the FEC operation circuit selection information stored in the FEC operation circuit selection information storage unit 532, the FEC operation circuit control unit 511 initializes the FEC operation circuit selection information (for example, to “0”) stored in the FEC operation circuit selection information storage unit 532.

The idle state information storage unit 512 stores idle state information. The idle state information is information that takes, for example, either “0” or “1”. For example, when the idle state information is “0”, this indicates that there is no received data (significant packet). The idle state information of “1” indicates that there is received data (significant packet).

The FEC setting management unit 531 stores the FEC operation circuit selection information in the FEC operation circuit selection information storage unit 532, for example, according to a command signal input to the communication apparatus 400 by an operator via the MCU 311 or 312 illustrated in FIG. 3. The FEC operation circuit selection information is information indicating an error correction circuit selected by an operator, for example, from the error correction circuits (for example, the EFEC operation circuit 523 and the UFEC operation circuit 524) in the error correction circuit 504.

The processing unit 111 in the transmission apparatus 110 illustrated in FIG. 1 may be realized, for example, by the framer 503, the error correction circuit 504, and the FEC operation circuit control unit 511. The transmission unit 112 in the transmission apparatus 110 illustrated in FIG. 1 may be realized, for example, by the OTN transmission unit 505 and the CFP 506.

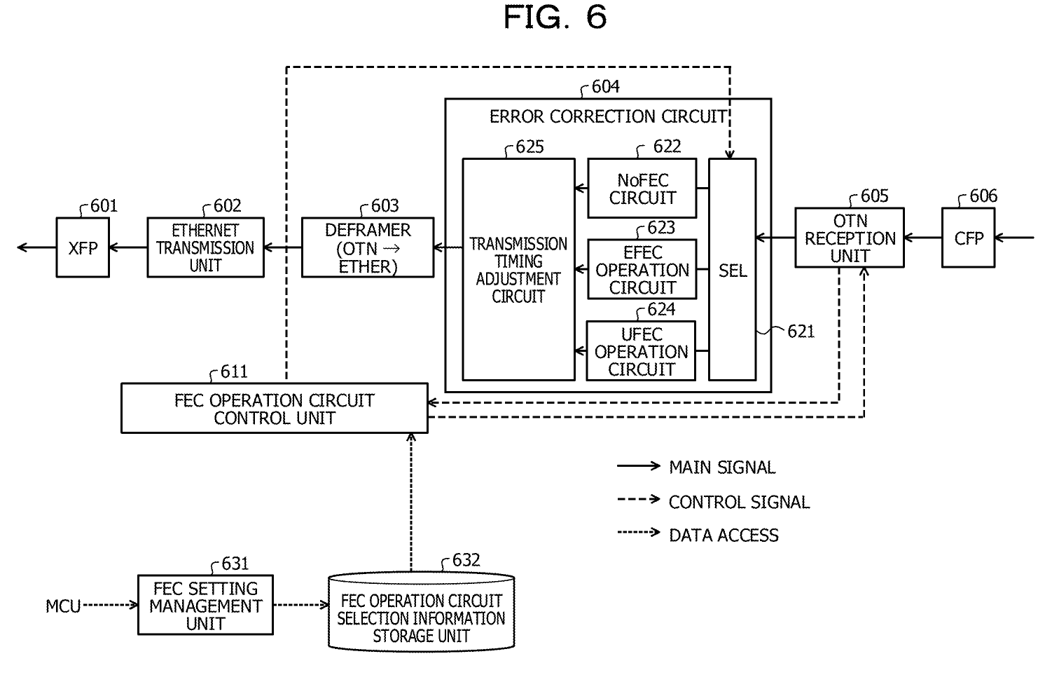

FIG. 6 illustrates an example of a configuration of a reception part of a communication apparatus. In FIG. 6, solid arrows indicate a main signal flow, broken line arrows indicate a control signal flow, and dotted line arrows indicate data access. The communication apparatus 400 illustrated in FIG. 4 includes, for example, an XFP 601, an Ethernet transmission unit 602, a deframer 603, an error correction circuit 604, an OTN reception unit 605, and a CFP 606, as illustrated in FIG. 6. The communication apparatus 400 also includes an FEC operation circuit control unit 611, an FEC setting management unit 631, and an FEC operation circuit selection information storage unit 632.

The FEC operation circuit control unit 611 may be realized, for example, by the CPU 407 illustrated in FIG. 4. The FEC operation circuit selection information storage unit 632 may be realized, for example, by the RAM 408 or the flash memory 409 illustrated in FIG. 4. The FEC setting management unit 631 may be realized, for example, by the CPU 407 and the communication interface 410 illustrated in FIG. 4.

The CFP 606 is included, for example, in the CFP 406 illustrated in FIG. 4. For example, the CFP 606 receives an OTN frame (main signal) from the optical layer transmission channel and outputs the received OTN frame to the OTN reception unit 605.

The OTN reception unit 605 is included, for example, in the optical layer transmission/reception unit 405 illustrated in FIG. 4. For example, the OTN reception unit 605 performs an optical layer reception process on the OTN frame output from the CFP 606 and reads out error correction circuit selection information from an OH (overhead) of the OTN frame subjected to the reception process.

The OTN reception unit 605 outputs an error correction mode notification to the FEC operation circuit control unit 611 to notify of the error correction circuit specified by the read error correction circuit selection information. In a case where an abnormality is detected in the read error correction circuit selection information, the OTN reception unit 605 outputs a failure notification to the FEC operation circuit control unit 611 to notify that reception of the error correction circuit selection information has failed. When an error correction circuit selection completion notification is output from the FEC operation circuit control unit 611 after the error correction mode notification or the failure notification is output, the OTN reception unit 605 outputs the OTN frame subjected to the reception process to the error correction circuit 604.

The error correction circuit 604 is included, for example, in the error correction coding/decoding processing unit 404 illustrated in FIG. 4. The error correction circuit 604 includes, for example, a selector 621, a NoFEC circuit 622, an EFEC operation circuit 623, a UFEC operation circuit 624, and a transmission timing adjustment circuit 625.

The selector 621 switches the error correction circuit 604 that is to be used to process the OTN frame output from the OTN reception unit 605. For example, the selector 621 outputs the OTN frame supplied from the OTN reception unit 605 to a circuit selected, according to the error correction circuit selection notification received from the FEC operation circuit control unit 611, from the NoFEC circuit 622, the EFEC operation circuit 623, and the UFEC operation circuit 624.

The NoFEC circuit 622 performs a process on the OTN frame output from the selector 621 to remove predetermined redundant bits that are added in a case where the error correction operation is not performed at the transmission side. The NoFEC circuit 622 then outputs the OTN frame subjected to the redundant bit removal to the transmission timing adjustment circuit 625.

The EFEC operation circuit 623 performs an EFEC error correction on the OTN frame output from the selector 621. The EFEC operation circuit 623 then outputs the resultant OTN frame subjected to the EFEC error correction to the transmission timing adjustment circuit 625. The UFEC operation circuit 624 performs a UFEC error correction on the OTN frame output from the selector 621. The UFEC operation circuit 624 then outputs the resultant OTN frame subjected to the UFEC error correction to the transmission timing adjustment circuit 625.

The transmission timing adjustment circuit 625 outputs, to the Ethernet transmission unit 602, the OTN frame output one of the NoFEC circuit 622, the EFEC operation circuit 623, and the UFEC operation circuit 624. The transmission timing adjustment circuit 625 adjusts the timing of outputting the OTN frame to the Ethernet transmission unit 602 thereby adjusting the timing of transmitting the Ethernet frame from the communication apparatus 400. For example, the transmission timing adjustment circuit 625 adjusts the transmission timing by adjusting a delay time that occurs in the NoFEC circuit 622, the EFEC operation circuit 623, or the UFEC operation circuit 624. This may reduce a loss of data or the like that might occur when the error correction circuit is switched.

The deframer 603 is included, for example, in the framer/deframer 403 illustrated in FIG. 4. For example, the deframer 603 convers (deframes) the OTN frame output from the error correction circuit 604 into an Ethernet packet and outputs the resultant converted Ethernet packet to the Ethernet transmission unit 602.

The Ethernet transmission unit 602 is included, for example, in the packet layer transmission/reception unit 402 illustrated in FIG. 4. For example, the Ethernet transmission unit 602 performs a packet layer transmission process on the Ethernet packet output from the deframer 603 and outputs the resultant Ethernet packet subjected to the transmission process to the XFP 601. The XFP 601 is included, for example, in the XFP 401 illustrated in FIG. 4. For example, the XFP 601 transmits the Ethernet packet output from the Ethernet transmission unit 602 to the packet layer.

When the error correction mode notification is output from the OTN reception unit 605, the FEC operation circuit control unit 611 outputs an error correction circuit selection notification to the error correction circuit 604 to notify of the error correction circuit specified by the error correction mode notification.

In a case where the failure notification is output from the OTN reception unit 605, the FEC operation circuit control unit 611 reads out the FEC operation circuit selection information stored in the FEC operation circuit selection information storage unit 632. The FEC operation circuit control unit 611 outputs an error correction circuit selection notification to the error correction circuit 604 to notify of the error correction circuit indicated by the read FEC operation circuit selection information.

After the FEC operation circuit control unit 611 outputs the error correction circuit selection notification to the error correction circuit 604, the FEC operation circuit control unit 611 outputs an error correction circuit selection completion notification to the OTN reception unit 605 to notify that the error correction circuit in the error correction circuit 604 has been switched.

The FEC setting management unit 631 and the FEC operation circuit selection information storage unit 632 are respectively similar, for example, to the FEC setting management unit 531 and the FEC operation circuit selection information storage unit 532 illustrated in FIG. 5. The FEC operation circuit selection information storage unit 632 stores, for example, the same FEC operation circuit selection information as that stored in the FEC operation circuit selection information storage unit 532 illustrated in FIG. 5.

The reception unit 121 in the reception apparatus 120 illustrated in FIG. 1 may be realized, for example, by the CFP 606 and the OTN reception unit 605. The processing unit 122 in the reception apparatus 120 illustrated in FIG. 1 may be realized, for example, by the error correction circuit 604, the deframer 603, and the FEC operation circuit control unit 611.

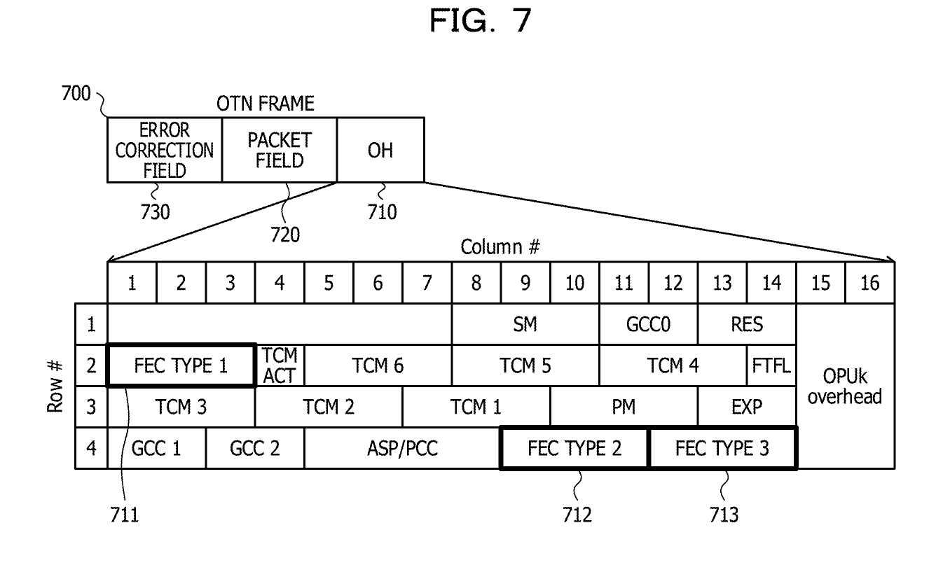

FIG. 7 illustrates an example of an OTN frame. For example, in the example illustrated in FIG. 2, the node 214 transmits an OTN frame 700 illustrated in FIG. 7 to the node 232. The OTN frame 700 includes an OH 710, a packet field 720, and an error correction field 730.

The OH 710 is an overhead representing a destination address, a transmission source, or the like of the OTN frame 700. The OH 710 includes the error correction circuit selection information described above. For example, the OH 710 includes areas 711 to 713 (FEC TYPE 1 to 3). The areas 711 to 713 are, for example, areas defined as reserved areas (RES) in ITU-T G.798, and each of these areas includes 3 bits. ITU-T stands for International Telecommunication Union-Telecommunication sector.

For example, the node 214 stores error correction circuit selection information of 3 bits equally in each of areas 711 to 713 of the OH 710 to be transmitted to the node 232. For example, in a case where NoFEC is selected as the error correction circuit, the node 214 stores “000” indicating NoFEC as the error correction circuit selection information equally in each of the areas 711 to 713. In a case where EFEC is selected as the error correction circuit, the node 214 stores “001” indicating EFEC as the error correction circuit selection information equally in each of the areas 711 to 713. In a case where UFEC is selected as the error correction circuit, the node 214 stores “010” indicating UFEC as the error correction circuit selection information equally in each of the areas 711 to 713.

As described above, the node 214 at the transmission side stores the same error correction circuit selection information in each of a plurality of areas (for example, areas 711 to 713) of the OH 710. This makes it possible for the node 232 at the receiving side to confirm whether the received error correction circuit selection information is correct or not by judging whether the error correction circuit selection information stored in the respective areas of the OH 710 of the received OTN frame 700 are identical to each other.

The packet field 720 is, for example, an area in which an Ethernet packet is stored. The error correction field 730 is, for example, an area that stores redundant bits added to an OTN frame by the error correction circuit 504 illustrated in FIG. 5.

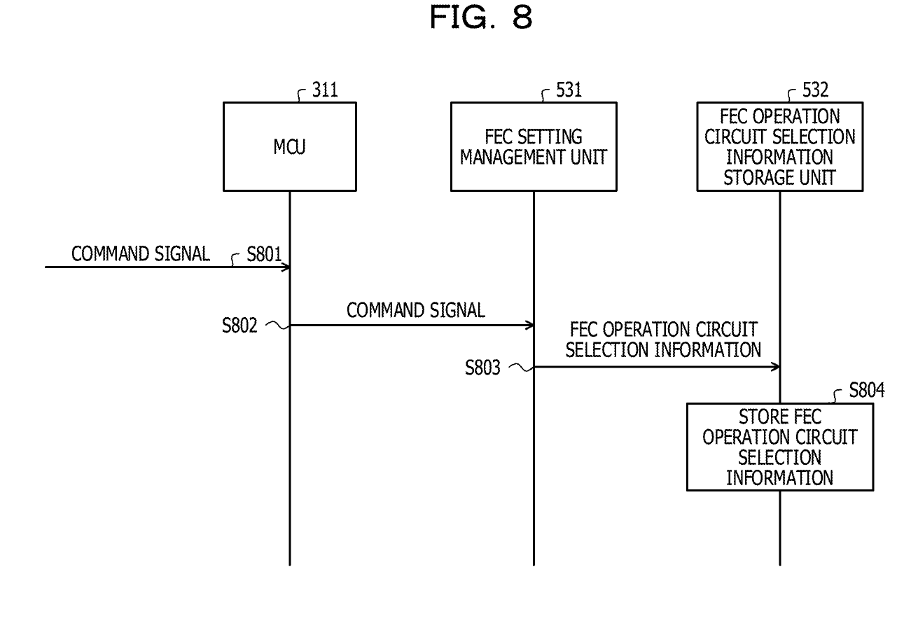

FIG. 8 illustrates an example of setting in terms of FEC operation circuit selection information. In FIG. 8, FEC operation circuit selection information is set according to a command signal input by an operator via the MCU 311 illustrated in FIG. 3 to the communication apparatus 400 at the transmission side illustrated in FIG. 5.

The MCU 311 accepts a command signal from an operator (operation S801). This command signal is, for example, a signal that specifies one of error correction circuits (for example, the EFEC operation circuit 523 and the UFEC operation circuit 524) that perform error correction operations in the error correction circuit 504. The MCU 311 outputs the command signal accepted in operation S801 to the FEC setting management unit 531 of the communication apparatus 400 (operation S802).

The FEC setting management unit 531 outputs, to the FEC operation circuit selection information storage unit 532, FEC operation circuit selection information indicating the error correction circuit specified by the command signal output in the operation S802 (operation S803). The FEC operation circuit selection information storage unit 532 stores the FEC operation circuit selection information output in operation S803 (operation S804), and the sequence of operations is completed.

The process has been described above for the case where the FEC operation circuit selection information is set in the FEC operation circuit selection information storage unit 532 of the communication apparatus 400 at the transmission side. Note that the process is similar for a case where the FEC operation circuit selection information is set in the FEC operation circuit selection information storage unit 632 of the communication apparatus 400 at the reception side.

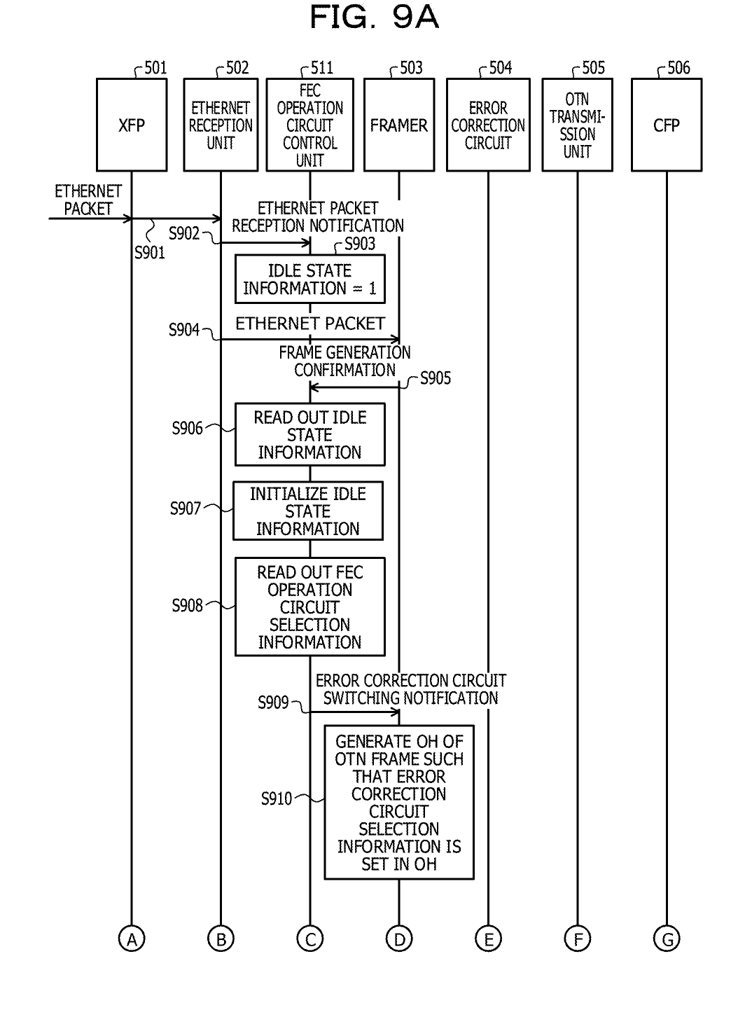

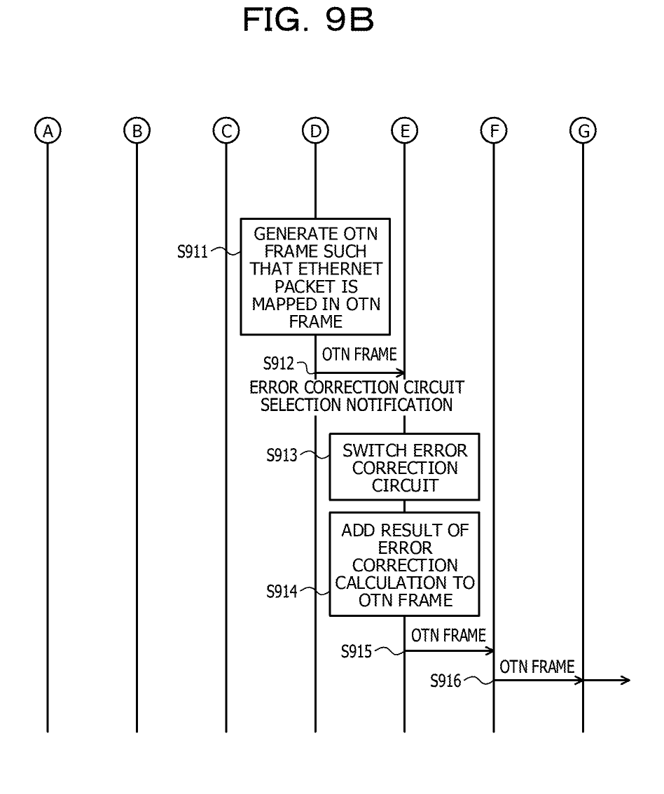

FIGS. 9A and 9B illustrate an example of a process performed in a communication apparatus at a transmission side when an Ethernet packet (significant packet) is received. In FIGS. 9A and 9B, by way of example, the communication apparatus 400 is applied to the node 214 illustrated in FIG. 2, and the node 214 receives a significant packet from the Ethernet side (for example, the node 213). In this case, for example, operations illustrated in FIGS. 9A and 9B are performed by respective elements of the communication apparatus 400 at the transmission side illustrated in FIG. 5.

Let it be assumed that the Ethernet reception unit 502 has received an Ethernet packet via the XFP 501 (operation S901). The Ethernet packet received in operation S901 is a significant packet including significant data. Because the received Ethernet packet is a significant packet including significant data, the Ethernet reception unit 502 outputs, to the FEC operation circuit control unit 511, an Ethernet packet reception notification indicating that the significant Ethernet packet has been received (operation S902).

In response to outputting the Ethernet packet reception notification from the Ethernet reception unit 502 in operation S902, the FEC operation circuit control unit 511 advances the process to operation S903. For example, the FEC operation circuit control unit 511 sets “1”, to indicate that there is received data, in the idle state information stored in the idle state information storage unit 512 (operation S903). The Ethernet reception unit 502 outputs the Ethernet packet received in operation S901 to the framer 503 (operation S904).

When one of periodical timings of generating an OTN frame comes, the framer 503 outputs a frame generation confirmation to the FEC operation circuit control unit 511 to confirm the generation of the OTN frame (operation S905).

In response to outputting of the frame generation confirmation from the framer 503 in operation S905, the FEC operation circuit control unit 511 reads out the idle state information from the idle state information storage unit 512 (operation S906). In this specific case, the idle state information read in operation S906 has a value of “1” set in operation S903 to indicate that there is received data.

The FEC operation circuit control unit 511 initializes the idle state information stored in the idle state information storage unit 512 (operation S907). For example, the FEC operation circuit control unit 511 sets “0” in the idle state information stored in the idle state information storage unit 512 to indicate that the status is in an idle state in which there is no received data.

In response to the value of “1” of the idle state information read in operation S906, the FEC operation circuit control unit 511 reads out the FEC operation circuit selection information from the FEC operation circuit selection information storage unit 532 (operation S908). The FEC operation circuit selection information is, for example, information set by an operator, and indicates, for example, either EFEC or UFEC.

The FEC operation circuit control unit 511 outputs an error correction circuit switching notification to the framer 503 to notify of the error correction circuit specified by the FEC operation circuit selection information read in operation S908 (operation S909). The framer 503 generates an OH of an OTN frame such that error correction circuit selection information is set in the OH to indicate the error correction circuit notified by the error correction circuit switching notification output in operation S909 from the FEC operation circuit control unit 511 (operation S910). For example, the framer 503 generates an OH 710 in which the same error correction circuit selection information is stored in each of a plurality of areas as illustrated in FIG. 7.

The framer 503 generates an OTN frame such that the OH generated in operation S910 is included in the OTN frame and the Ethernet packet output in operation S904 from the Ethernet reception unit 502 is mapped in the OTN frame (operation S911). The framer 503 outputs the OTN frame generated in operation S911 to the error correction circuit 504 (operation S912). Furthermore, in operation S912, the framer 503 outputs an error correction circuit selection notification to the error correction circuit 504 to notify of the error correction circuit specified by the error correction circuit switching notification output in operation S909.

Based on the error correction circuit selection notification output in operation S912, the error correction circuit 504 switches an error correction circuit that is to be used to process the OTN frame (operation S913). For example, the error correction circuit 504 switches the selector 521 such that the OTN frame is to be output to the error correction circuit which is one of the EFEC operation circuit 523 and the UFEC operation circuit 524 and which is one specified by the error correction circuit selection notification.

In the error correction circuit 504, the error correction circuit selected via the switching in operation S913 performs an error correction calculation on the OTN frame output in operation S912, and adds redundant bits obtained as a result of the error correction calculation to the OTN frame (operation S914). Next, at a timing of transmitting the OTN frame by the communication apparatus 400, the error correction circuit 504 outputs the OTN frame added, in operation S914, with the result of the error correction calculation to the OTN transmission unit 505 (operation S915).

The OTN transmission unit 505 transmits the OTN frame output in operation S915 to a counterpart apparatus (for example, the node 232) via the CFP 506 (operation S916), and thus the sequence of operations performed in response to receiving an Ethernet packet (a significant packet) is completed.

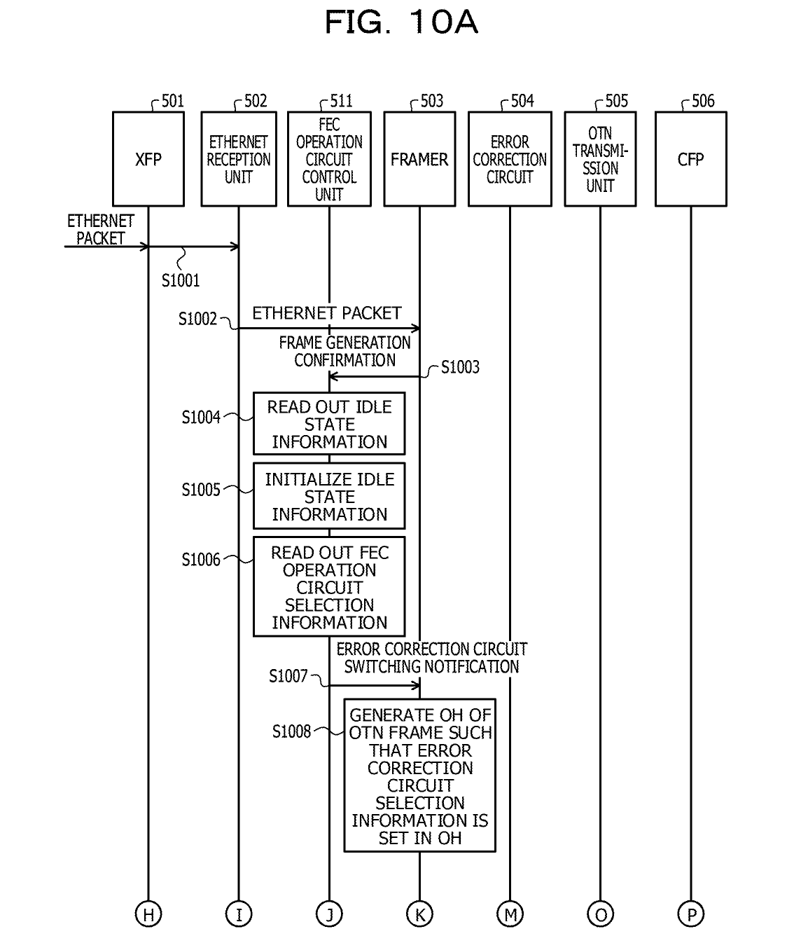

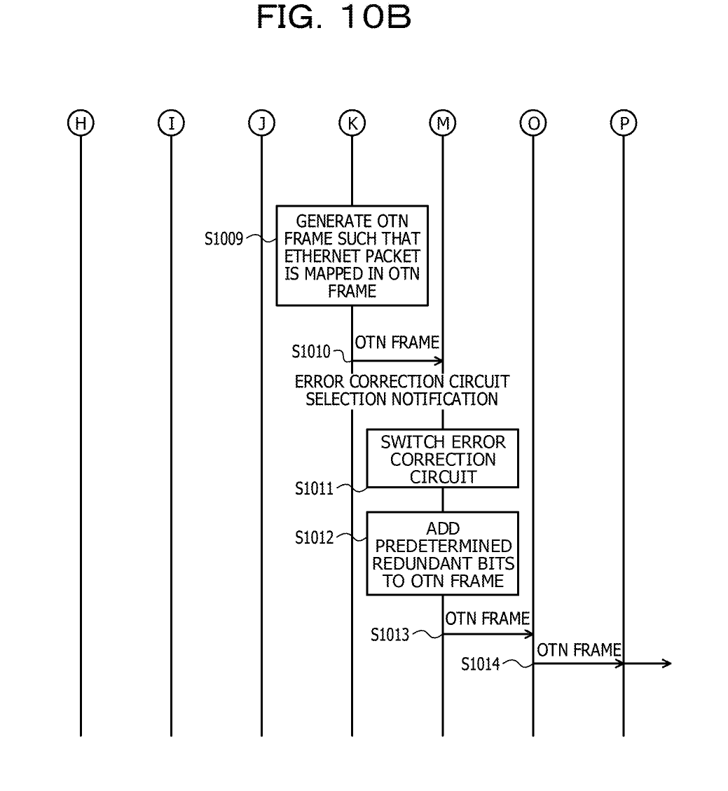

FIGS. 10A and 10B illustrate an example of a process performed in a communication apparatus at a transmission side when an Ethernet packet (idle packet) is received. In FIGS. 10A and 10B, by way of example, the communication apparatus 400 is applied to the node 214 illustrated in FIG. 2, and the node 214 receives an idle packet from the Ethernet side (for example, the node 213). In this case, for example, operations illustrated in FIGS. 10A and 10B are performed by respective elements of the communication apparatus 400 at the transmission side illustrated in FIG. 5.

Let it be assumed that the Ethernet reception unit 502 has received an Ethernet packet via the XFP 501 (operation S1001). The Ethernet packet received in operation S1001 is an idle packet including no significant data. In this case, because the received Ethernet packet is an idle packet including no data, the Ethernet reception unit 502 does not output the Ethernet packet reception notification described above to the FEC operation circuit control unit 511. The Ethernet reception unit 502 outputs the Ethernet packet received in operation S1001 to the framer 503 (operation S1002).

When a timing of transmitting the OTN frame by the communication apparatus 400 comes, the framer 503 outputs a frame generation confirmation to the FEC operation circuit control unit 511 to confirm the generation of the OTN frame (operation S1003). In response to outputting of the frame generation confirmation from the framer 503 in operation S1003, the FEC operation circuit control unit 511 reads out the idle state information from the idle state information storage unit 512 (operation S1004). In this specific case, the idle state information read in operation S1004 has a value of “0” indicating that there is no received data.

The FEC operation circuit control unit 511 initializes the idle state information stored in the idle state information storage unit 512 (operation S1005). For example, the FEC operation circuit control unit 511 sets “0” in the idle state information stored in the idle state information storage unit 512 to indicate that the status is in an idle state in which there is no received data. In the example illustrated in FIGS. 10A and 10B, operation S1005 may be removed.

The FEC operation circuit control unit 511 reads out the FEC operation circuit selection information from the FEC operation circuit selection information storage unit 532 (operation S1006). In response to the value of “0” of the idle state information read in operation S1004, the FEC operation circuit control unit 511 outputs an error correction circuit switching notification to the framer 503 to specify NoFEC as the error correction circuit (operation S1007).

Operations S1008 to S1014 illustrated in FIGS. 10A and 10B are respectively similar to the operations S910 to S916 illustrated in FIGS. 9A and 9B. However, in operation S1011, the error correction circuit 504 switches the selector 521 such that the OTN frame is to be output to the NoFEC circuit 522. Furthermore, in operation S1012, the error correction circuit 504 does not perform the error correction calculation and adds, to the OTN frame, predetermined redundant bits that are employed in the case where no error correction operation is performed. Via the operations illustrated in FIGS. 10A and 10B, the OTN frame, in which the idle packet received by the communication apparatus 400 is mapped and for which no error correction calculation is performed, is transmitted to the counterpart apparatus.

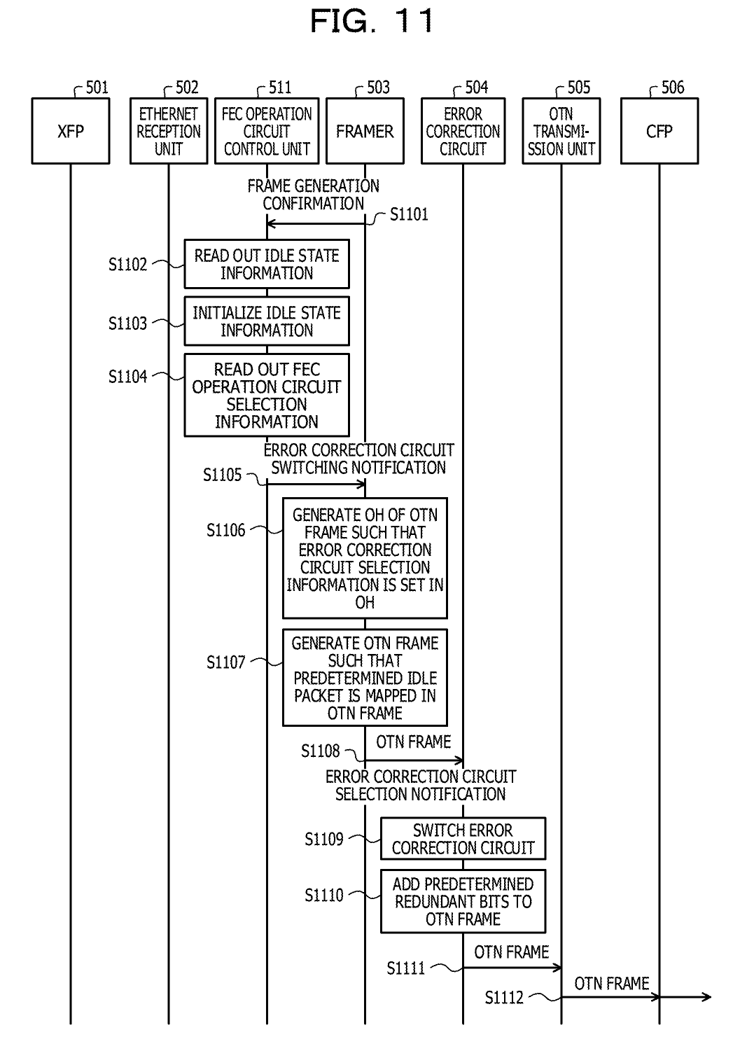

FIG. 11 illustrates an example of a process performed in a communication apparatus at a transmission side when no Ethernet packet is received. In FIG. 11, by way of example, the communication apparatus 400 is applied to the node 214 illustrated in FIG. 2, and the node 214 does not receive an Ethernet packet from the Ethernet side over a period with a predetermined length

Even in this case, because the OTN frame transmission is performed periodically, the communication apparatus 400 periodically generates an OTN frame. In this case, operations illustrated in FIG. 11 are performed by respective elements of the communication apparatus 400 at the transmission side illustrated in FIG. 5.

Even in a state in which no Ethernet packet is received, when one of periodical timings of generating an OTN frame comes, the framer 503 outputs a frame generation confirmation to the FEC operation circuit control unit 511 to confirm the generation of the OTN frame (operation S1101). Operations S1102 to S1112 illustrated in FIG. 11 are respectively similar to the operations S1004 to S1014 illustrated in FIGS. 10A and 10B. However, in operation S1107, the framer 503 generates an OTN frame such that a predetermined idle packet (Ethernet packet) is mapped in the OTN frame. Via the operations illustrated in FIG. 11, the OTN frame, in which the idle packet is mapped and for which no error correction calculation is performed, is transmitted to the counterpart apparatus.

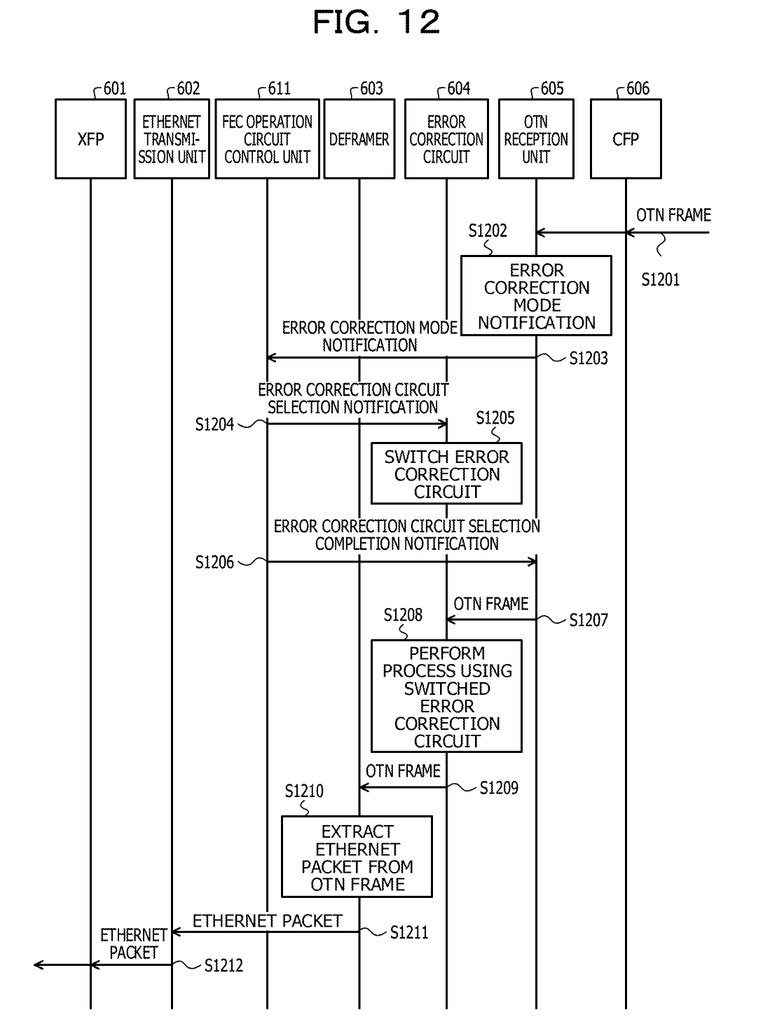

FIG. 12 illustrates an example of a process performed in a communication apparatus at a reception side when a valid OTN frame (significant packet) is received. In FIG. 12, by way of example, the communication apparatus 400 is applied to the node 232 illustrated in FIG. 2, and the node 232 receives an OTN frame from the OTN side (the node 214). Here let it be assumed that a significant packet is mapped in this OTN frame and the OH of this OTN frame has been correctly received. In this case, for example, operations illustrated in FIG. 12 are performed by respective elements of the communication apparatus 400 at the reception side illustrated in FIG. 6.

The OTN reception unit 605 receives, via the CFP 606, the OTN frame transmitted from the communication apparatus at the transmission side (operation S1201). The OTN frame received in this operation S1201 is, for example, an OTN frame in which a significant packet is mapped. Next, the OTN reception unit 605 reads out the error correction circuit selection information from the OH of the OTN frame received in operation S1201 (operation S1202).

In the example illustrated in FIG. 12, the error correction circuit selection information stored in the respective plurality of areas (for example, the areas 711 to 713 illustrated in FIG. 7) of the OH of the OTN frame are identical to each other. This makes it possible to judge whether the error correction circuit selection information of the OH of the OTN frame is correctly received. In this case, the OTN reception unit 605 outputs an error correction mode notification to the FEC operation circuit control unit 611 to notify of the error correction circuit specified by the error correction circuit selection information read in operation S1202 (operation S1203).

The FEC operation circuit control unit 611 outputs an error correction circuit selection notification to the error correction circuit 604 to notify of the error correction circuit notified by the error correction mode notification output in operation S1203 (operation S1204).

Based on the error correction circuit selection notification output in operation S1204, the error correction circuit 604 switches an error correction circuit that is to be used to process the OTN frame (operation S1205). For example, the error correction circuit 604 switches the selector 621 such that the OTN frame is to be output to the error correction circuit which is one of the EFEC operation circuit 623 and UFEC operation circuit 624 and which is one specified by the error correction circuit selection notification.

The FEC operation circuit control unit 611 outputs an error correction circuit selection completion notification to the OTN reception unit 605 to notify that the error correction circuit in the error correction circuit 604 has been switched (operation S1206).

In response to the outputting of the error correction circuit selection completion notification in operation S1206, the OTN reception unit 605 outputs the OTN frame received in operation S1201 to the error correction circuit 604 (operation S1207). As described above, after the specified error correction circuit in the error correction circuit 604 has been selected, the OTN reception unit 605 outputs the received OTN frame to the error correction circuit 604.

The error correction circuit 604 performs the process on the OTN frame output in operation S1207 by using the error correction circuit selected via the switching in operation S1205 (operation S1208). Thus, the error correction is performed on the OTN frame. The error correction circuit 604 outputs the OTN frame subjected to the process in operation S1208 to the deframer 603 (operation S1209).

The deframer 603 extracts an Ethernet packet from the OTN frame output in operation S1209 (operation S1210). The deframer 603 outputs the Ethernet packet extracted in operation S1210 to the Ethernet transmission unit 602 (operation S1211). The Ethernet transmission unit 602 transmits the Ethernet packet output in operation S1211 to the Ethernet side via the XFP 601 (operation S1212), and thus the sequence of operations, performed for the case where an OTN frame in which a significant packet is mapped, is completed. In operation S1212, the Ethernet transmission unit 602 transmits the Ethernet packet, for example, to the node 231 illustrated in FIG. 2.

Via the operations illustrated in FIG. 12, the significant packet (Ethernet packet) mapped in the OTN frame is extracted and transmitted to the Ethernet side. The process has been described above that is performed when an OTN frame including a significant packet mapped therein is received. In a case where an OTN frame including an idle packet mapped therein is received, a process is performed in a similar manner. However, in this case, an idle packet (Ethernet packet) mapped in the OTN frame is extracted and transmitted to the Ethernet side.

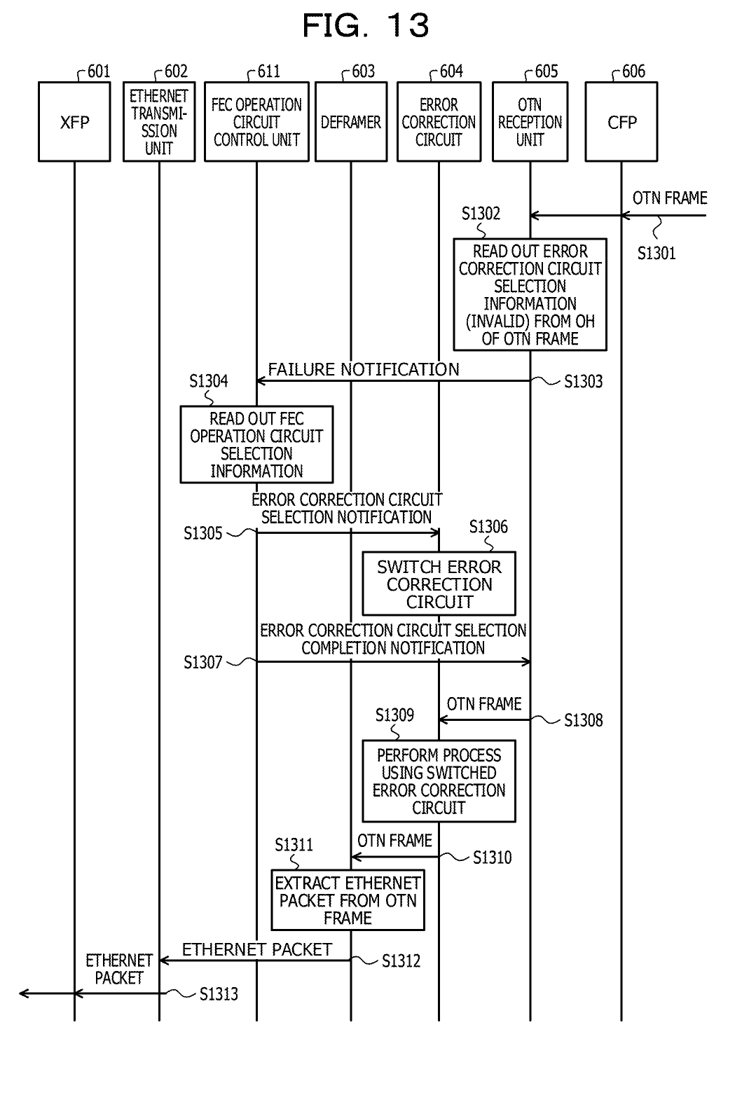

FIG. 13 illustrates an example of a process performed in a communication apparatus at a reception side when an invalid OTN frame (significant packet) is received. In FIG. 13, by way of example, the communication apparatus 400 is applied to the node 232 illustrated in FIG. 2, and the node 232 receives an OTN frame from the OTN side (node 214). Here let it be assumed that a significant packet is mapped in this OTN frame and an OH of this OTN frame has been received incorrectly. In this case, operations illustrated in FIG. 13 are performed by respective elements of the communication apparatus 400 at the reception side illustrated in FIG. 6.

Operations S1301 to S1303 illustrated in FIG. 13 are respectively similar to the operations S1201 to S1203 illustrated in FIG. 12. In the example illustrated in FIG. 13, it is assumed that there is a difference among error correction circuit selection information stored in the respective plurality of areas of the OH read in operation S1302. In this case, because the OH of the OTN frame has an error, it is possible to judge that error correction circuit selection information has been received incorrectly. In this case, in operation S1303, the OTN reception unit 605 outputs a failure notification to the FEC operation circuit control unit 611 to notify that the reception of the error correction circuit selection information has failed.

After operation S1303, in response to the outputting the failure notification in operation S1303, the FEC operation circuit control unit 611 reads out the FEC operation circuit selection information from the FEC operation circuit selection information storage unit 632 (operation S1304).

The FEC operation circuit control unit 611 outputs an error correction circuit selection notification to the error correction circuit 604 to notify of an error correction circuit indicated by the FEC operation circuit selection information read in operation S1304 (operation S1305). Operations S1306 to S1313 illustrated in FIG. 13 are respectively similar to the operations S1205 to S1212 illustrated in FIG. 12.

Via the operations illustrated in FIG. 13, in a case where the reception of the error correction circuit selection information fails, it is possible to perform the error correction using the error correction circuit indicated by the FEC operation circuit selection information stored in the FEC operation circuit selection information storage unit 632. Thus, in a case where a receiving OTN frame includes a significant packet mapped therein, it is possible to perform the error correction using the error correction circuit corresponding to the error correction circuit used at the transmission side and correctly extract the significant packet.

On the other hand, in a case where a received OTN frame includes an idle packet mapped therein, the error correction is performed although no error correction calculation was performed at the transmission side. Thus, even when extracting of an idle packet in the error correction fails, the failure in extracting the idle packet does not exert any influence on the Ethernet side. Note that in this case, because the extraction of the Ethernet packet (idle packet) in operation S1311 in FIG. 13 fails, the processing flow does not proceed to operation S1312.

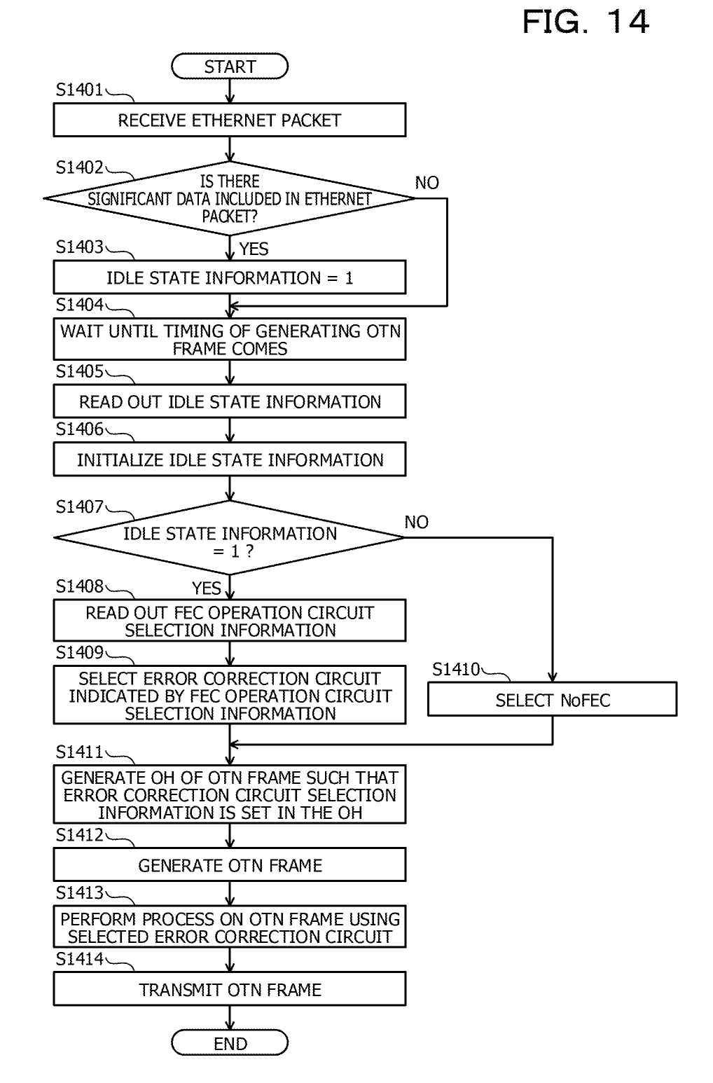

FIG. 14 illustrates an example of a process performed in a communication apparatus at a transmission side when an Ethernet packet is received. In FIG. 14, by way of example, the communication apparatus 400 is applied to the node 214 illustrated in FIG. 2, and the node 214 receives an Ethernet packet (a significant packet or an idle packet) from the Ethernet side. In this case, the communication apparatus 400 repeatedly performs operations illustrated, for example, in FIG. 14.

The communication apparatus 400 receives an Ethernet packet from the Ethernet side (operation S1401). The operation S1401 is executed, for example, by the XFP 501 and the Ethernet reception unit 502 illustrated in FIG. 5. The communication apparatus 400 determines whether the Ethernet packet received in operation S1401 includes significant data (operation S1402). The operation S1402 is executed, for example, by the Ethernet reception unit 502 illustrated in FIG. 5.

In a case where it is determined in operation S1402 that the Ethernet packet includes no significant data (No in operation S1402), the communication apparatus 400 advances the process to operation S1404. In a case where the Ethernet packet includes significant data (Yes in operation S1402), the communication apparatus 400 sets “1”, to indicate that there is received data, in the idle state information (operation S1403). The operation S1403 is executed, for example, by the FEC operation circuit control unit 511 illustrated in FIG. 5.

The communication apparatus 400 waits until timing of generating an OTN frame comes (operation S1404). The operation S1404 is executed, for example, by the framer 503 illustrated in FIG. 5. The communication apparatus 400 reads out the idle state information from the idle state information storage unit 512 (operation S1405). The operation S1405 is executed, for example, by the FEC operation circuit control unit 511 illustrated in FIG. 5.

The communication apparatus 400 initializes the idle state information stored in the idle state information storage unit 512 (operation S1406). The operation S1406 is executed, for example, by the FEC operation circuit control unit 511 illustrated in FIG. 5. The communication apparatus 400 determines whether the idle state information read in operation S1405 has a value of “1” indicating that there is data (operation S1407). The operation S1407 is executed, for example, by the FEC operation circuit control unit 511 illustrated in FIG. 5.

In a case where it is determined in operation S1407 that the idle state information has a value of “1” (Yes in operation S1407), the communication apparatus 400 reads out the FEC operation circuit selection information from the FEC operation circuit selection information storage unit 532 (operation S1408). The operation S1408 is executed, for example, by the FEC operation circuit control unit 511 illustrated in FIG. 5. Next, the communication apparatus 400 selects an error correction circuit indicated by the FEC operation circuit selection information read in operation S1408 (operation S1409). Thereafter, the processing flow proceeds to operation S1411. The operation S1409 is executed, for example, by the FEC operation circuit control unit 511 illustrated in FIG. 5.

In a case where it is determined in operation S1407 that the value of the idle state information is not “1” (No in operation S1407), the communication apparatus 400 selects NoFEC (operation S1410). Next, the communication apparatus 400 generates an OH of an OTN frame such that the error correction circuit selection information indicating the error correction circuit selected in operation S1409 or operation S1410 is described in the OH (operation S1411). The operation S1411 is executed, for example, by the framer 503 illustrated in FIG. 5.

The communication apparatus 400 generates an OTN frame such that the OTN frame includes the OH generated in operation S1411 and the Ethernet packet received in operation S1401 is mapped in the OTN frame (operation S1412). The operation S1412 is executed, for example, by the framer 503 illustrated in FIG. 5.

The communication apparatus 400 performs a process on the OTN frame generated in operation S1412 by using the error correction circuit selected in operation S1409 or operation S1410 (operation S1413). The operation S1413 is executed, for example, by the error correction circuit 504 illustrated in FIG. 5.

The communication apparatus 400 transmits the OTN frame subjected to the process in operation S1413 to a counterpart apparatus (for example, the node 232) (operation S1414), and thus the sequence of operations performed in response to receiving an Ethernet packet is completed. Operation S1414 is executed, for example, by the OTN transmission unit 505 and the CFP 506.

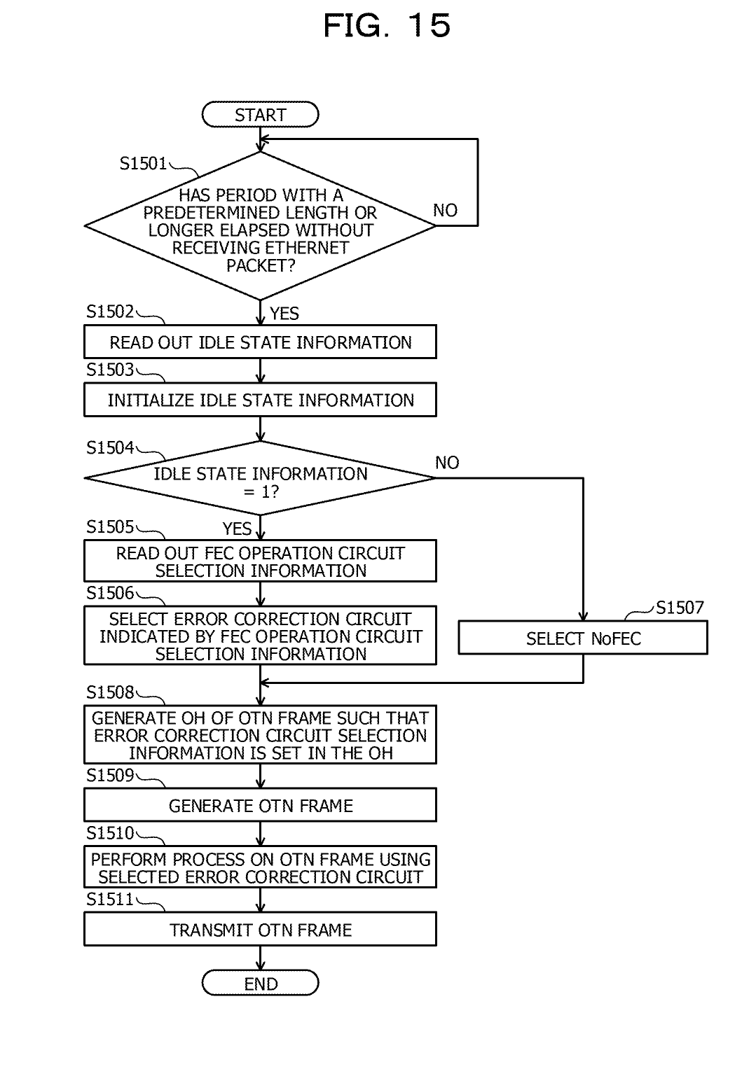

FIG. 15 illustrates an example of a process performed in a communication apparatus at a transmission side when no Ethernet packet is received. In FIG. 15, by way of example, the communication apparatus 400 is applied to the node 214 illustrated in FIG. 2, and the node 214 does not receive an Ethernet packet from the Ethernet side over a period with a predetermined length. In this case, for example, the communication apparatus 400 repeatedly performs the operations illustrated FIG. 14 and operations illustrated in FIG. 15.

The communication apparatus 400 determines whether the period with the predetermined length or longer has elapsed without receiving an Ethernet packet from the Ethernet (operation S1501). If no, the communication apparatus 400 waits until the period with the predetermined length or longer has elapsed without receiving an Ethernet packet (No in operation S1501). Operation S1501 is executed, for example, by the framer 503.

In a case where it is determined in operation S1501 that the period with the predetermined length or longer has elapsed without receiving an Ethernet packet (Yes in operation S1501), the communication apparatus 400 advances the process to operation S1502. Operations S1502 to S1511 illustrated in FIG. 15 are similar to the operations S1405 to S1414 illustrated in FIG. 14.

In the example illustrated in FIG. 15, the process may be modified such that operations S1502 to S1506 are removed, and the processing flow proceeds from operation S1501 to operation S1507. In the example illustrated in FIG. 15, by way example, the determination is made in operation S1501 as to whether the period with the predetermined length or longer has elapsed while receiving no Ethernet packet from the Ethernet side. However, the process is not limited to such an example. For example, in operation S1501, a determination may be made as to whether timing of generating an OTN frame has come.

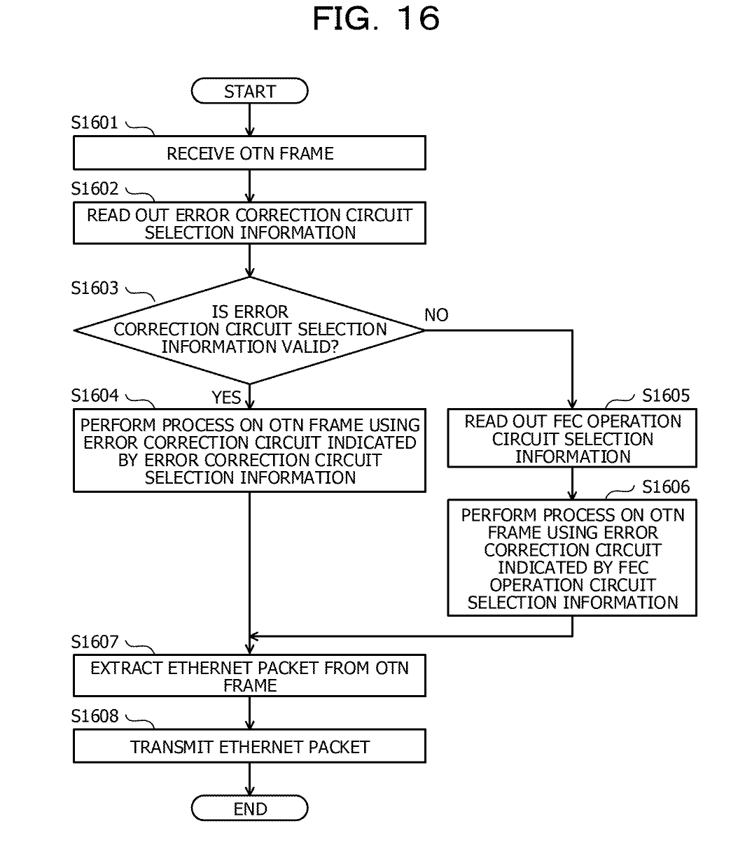

FIG. 16 illustrates an example of a process performed in a communication apparatus according to an embodiment at a reception side when an OTN frame is received. In FIG. 16, by way of example, the communication apparatus 400 is applied to the node 232 illustrated in FIG. 2, and the node 232 receives an OTN frame from the OTN side (the node 214). In this case, for example, the communication apparatus 400 repeatedly performs operations illustrated in FIG. 16.

The communication apparatus 400 receives an OTN frame from a counterpart apparatus (for example, the node 214) (operation S1601). The operation S1601 is executed, for example, by the CFP 606 and the OTN reception unit 605 illustrated in FIG. 6. The communication apparatus 400 reads out error correction circuit selection information from an OH of the OTN frame received in operation S1601 (operation S1602). The operation S1602 is executed, for example, by the OTN reception unit 605 illustrated in FIG. 6.

The communication apparatus 400 determines whether the error correction circuit selection information read in operation S1602 is valid (operation S1603). More specifically, for example, operation S1603 is executed by the OTN reception unit 605 illustrated in FIG. 6 by determining whether that there is no difference among error correction circuit selection information stored in the respective plurality of areas of the OH of the OTN frame.

In a case where it is determined in operation S1603 that the read error correction circuit selection information is valid (Yes in operation S1603), the communication apparatus 400 advances the process to operation S1604. For example, the communication apparatus 400 performs a process on the OTN frame received in operation S1601 by using the error correction circuit indicated by the error correction circuit selection information (operation S1604), and the communication apparatus 400 then advances the process to operation S1607. The operation S1604 is executed, for example, by the error correction circuit 604 illustrated in FIG. 6.

In a case where it is determined in operation S1603 that the read error correction circuit selection information is not valid (No in operation S1603), the communication apparatus 400 reads out the FEC operation circuit selection information from the FEC operation circuit selection information storage unit 632 (operation S1605). The operation S1605 is executed, for example, by the FEC operation circuit control unit 611 illustrated in FIG. 6.

The communication apparatus 400 performs a process on the OTN frame received in operation S1601 by using the error correction circuit indicated by the FEC operation circuit selection information read in operation S1605 (operation S1606). The operation S1606 is executed, for example, by the error correction circuit 604 illustrated in FIG. 6.

The communication apparatus 400 extracts an Ethernet packet from the OTN frame subjected to the process in operation S1604 or operation S1606 (operation S1607). Operation S1607 is executed, for example, by the deframer 603 illustrated in FIG. 6.

The communication apparatus 400 transmits the Ethernet packet extracted in operation S1607 to the Ethernet side (for example, the node 231 illustrated in FIG. 2) (operation S1608), and thus the sequence of operations performed in response to receiving the OTN frame is completed.

As described above, the communication apparatus 400 performs the error correction coding process on the OTN frame in a mode depending on whether the Ethernet packet stored in the OTN frame includes significant data. This makes it possible to perform an error correction coding process with low power consumption (for example, NoFEC), for example, on an OTN frame including no significant data thereby achieving a reduction in consumption power.

As described above, in the transmission apparatus, the reception apparatus, and the reception method described above, a reduction in consumption power is achieved.

Advances in optical transmission technology and packet transmission technology have made it possible to realize transmission apparatuses that support transmission in a plurality of different network layers (hereinafter referred to simply as layers). These transmission apparatuses have a layer-layer conversion capability, for example, for converting from an optical layer to a placket layer or from a packet layer to an optical layer, and also have an error correction capability.

Long-distance data transmission is realized, for example, using an optical layer such as OTN. The packet layer is a higher layer than the optical layer. By using such a transmission apparatus or a transmission system, high-capacity and long-distance data transmission service is provided.

To realize high-capacity and long-distance data transmission using the optical layer, a data error correction function is important. However, user data (data received from a packet layer) is not included in all data transmitted between transmission apparatuses or transmission systems using the optical layer.

However, regardless of whether user data is included in a signal transmitted from the optical layer, the error correction capability of the optical layer is continuously operated, which may cause an apparatus or a system to consume power uselessly.

For example, when the apparatus the system described above is being operated, presence/absence of user data is monitored, and an optimum error correction circuit is selected depending on the presence/absence of user data. When the error correction circuit used at the optical layer transmission side is changed, then in response, the error correction circuit at the opposing optical layer reception side is automatically changed to the same one. When the error correction circuit is changed during the operation of the apparatus or the system, the changing is performed such that no loss of an optical layer signal occurs.

As described above, during the operation of the apparatus or the system, the determination is made as to whether there is user data, and the optimum error correction circuit is selected depending on the result of the determination. Thus, it is possible to reduce the consumption power of the transmission apparatus or the transmission system. The same error correction circuit is automatically selected in apparatuses or systems at both the transmission side and the reception side. The changing of the error correction circuit during the operation of the apparatus or the system is performed such that no loss of an optical layer signal occurs.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A transmission apparatus comprising:
a memory;
a processor coupled to the memory,
wherein the processor:
generates a frame including an input packet;
performs, on the frame, a coding process regarding an error correction and depending on whether the packet includes significant data; and
transmits the frame subjected to the coding process.

2. The transmission apparatus according to claim 1, wherein the processor stores information indicating the coding process performed on the frame in a header of the frame.

3. The transmission apparatus according to claim 2, wherein the processor stores information indicating the coding process in each of a plurality of areas of the header.

4. The transmission apparatus according to claim 1, wherein the processor:
in a case where the packet includes significant data, performs, on the frame, a first coding process which adds a redundant bit calculated in the error correction to the frame; and
in a case where the packet includes no significant data, performs a second coding process, which consumes less power than the first coding process, on the frame.

5. The transmission apparatus according to claim 4, wherein the second coding process is a process of adding a specific redundant bit to the frame without performing the error correction.

6. The transmission apparatus according to claim 4, wherein in a case where the packet is not input, the processor generates a frame including an idle packet, and performs the second coding process on the frame.

7. The transmission apparatus according to claim 6, wherein
the packet is a packet that is input irregularly, and
the processor generates the frame to be transmitted periodically.

8. The transmission apparatus according to claim 1, wherein the frame is an OTN (Optical Transport Network) frame.

9. A reception apparatus comprising:
a memory; and
a processor coupled to the memory;
where the processor:
receives a frame transmitted by a transmission apparatus configured to store, in a header of the frame, information indicating a coding process, which is performed on the frame, regarding an error correction and depending on whether a packet included in the frame includes significant data;
performs a decoding process corresponding to the coding process performed by the transmission apparatus, based on the information included in the header of the received frame; and
acquires the packet from the frame subjected to the decoding process.

10. The reception apparatus according to claim 9, wherein the transmission apparatus stores information indicating the coding process performed on the frame in a header of the frame.

11. The reception apparatus according to claim 10, wherein the transmission apparatus stores information indicating the coding process in each of a plurality of areas of the header.

12. The reception apparatus according to claim 9, wherein transmission apparatus:
in a case where the packet includes significant data, performs, on the frame, a first coding process which adds a redundant bit calculated in the error correction to the frame; and
in a case where the packet includes no significant data, performs a second coding process, which consumes less power than the first coding process, on the frame.

13. The reception apparatus according to claim 12, wherein the second coding process is a process of adding a specific redundant bit to the frame without performing the error correction.

14. The reception apparatus according to claim 12, wherein in a case where the packet is not input, the transmission apparatus generates a frame including an idle packet, and performs the second coding process on the frame.

15. The reception apparatus according to claim 14, wherein
the packet is a packet that is input irregularly, and
the transmission apparatus generates the frame to be transmitted periodically.

16. The reception apparatus according to claim 9, wherein the frame is an OTN (Optical Transport Network) frame.

17. A reception method comprising:
receiving, by a computer, a frame transmitted by a transmission apparatus configured to store, in a header of the frame, information indicating a coding process, which is performed on the frame, regarding an error correction and depending on whether a packet included in the frame includes significant data;
performing a decoding process corresponding to the coding process performed by the transmission apparatus, based on the information included in the header of the received frame; and
acquiring the packet from the frame subjected to the decoding process.

18. The reception method according to claim 17, wherein the transmission apparatus stores information indicating the coding process performed on the frame in a header of the frame.

19. The reception method according to claim 18, wherein the transmission apparatus stores information indicating the coding process in each of a plurality of areas of the header.

20. The reception method according to claim 17, wherein transmission apparatus:
in a case where the packet includes significant data, performs, on the frame, a first coding process which adds a redundant bit calculated in the error correction to the frame; and
in a case where the packet includes no significant data, performs a second coding process, which consumes less power than the first coding process, on the frame.
